(19) United States
(12) Patent Application Publication
(10) Pub. No.: US 2012/0132660 A1
(43) Pub. Date: May 31, 2012

(54) DEVICE HOUSING AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); LI-QUAN PENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/156,550

(22) Filed: Jun. 9, 2011

(30) Foreign Application Priority Data
Nov. 29, 2010 (CN) 201010563904.7

(51) Int. Cl. B65D 8/04; C23C 14/12

(52) U.S. Cl. 220/626; 427/525

(57) ABSTRACT

A device housing is provided. The device housing includes a substrate, and an anti-fingerprint film formed on the substrate. The substrate has roughness in a range from about 0.05 μm to about 0.25 μm. The anti-fingerprint film is a nano-composite coating consisting essentially of polytetrafluoroethylene. A method for making the device housing is also described.

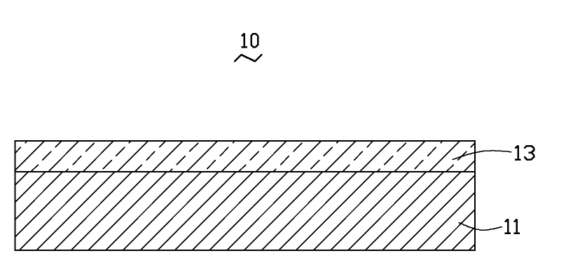

### BACKGROUND

1. Technical Field

The present disclosure relates to device housings, particularly to a device housing having an anti-fingerprint property and a method for making the device housing.

2. Description of Related Art

Many electronic device housings are coated with anti-fingerprint film. These anti-fingerprint films are commonly a paint containing organic anti-fingerprint substances. However, the print films are thick (commonly 2 μm-4 μm) and not very effective. Furthermore, the paint may not be environmentally friendly.

Therefore, there is room for improvement within the art.

### BRIEF DESCRIPTION OF THE FIGURE

Many aspects of the device housing can be better understood with reference to the following FIGURE. The components in the FIGURE are not necessarily drawn to scale, the emphasis instead being placed upon clearly illustrating the principles of the device housing.

The FIGURE is a cross-section view of an exemplary embodiment of a device housing.

### DETAILED DESCRIPTION

The FIGURE shows a device housing 10 according to an exemplary embodiment. The device housing 10 includes a substrate 11, and an anti-fingerprint film 13 formed on a surface of the substrate 11.

The substrate 11 may be made of metal or non-metal material. The metal may be selected from a group consisting of stainless steel, aluminum, aluminum alloy, copper, and copper alloy. The non-metal material may be plastic or ceramic. The substrate 11 has a coarse or rugged surface having roughness in a range from about 0.05 μm to about 0.25 μm. The coarse or rugged surface can be achieved by means of sandblasting, laser etching, or chemical etching.

The anti-fingerprint film 13 is a nano-composite coating consisting essentially of polytetrafluoroethylene (PTFE). The coating can be provided by depositing polytetrafluoroethylene onto the substrate 11 using conventional deposition techniques, such as ion plating. It will be appreciated that other deposition methods of providing the nano-composite coating can also be employed. The anti-fingerprint film 13 made in this manner has a good anti-fingerprint property.

The anti-fingerprint film 13 is transparent. The thickness of the anti-fingerprint film 13 is under 2000 nm. In this exemplary embodiment, the anti-fingerprint film 13 has a thickness of only about 100 nm to about 500 nm. The anti-fingerprint film 13 is directly formed on the coarse or rugged surface of the substrate 11. The coarse or rugged surface may improve the binding force between the anti-fingerprint film 13 and the substrate 11 to allow the anti-fingerprint film 13 to be tightly bonded to the coarse or rugged surface of the substrate 11.

A method for making the device housing 10 may include the following steps:

The substrate 11 is pretreated. The pre-treating process may include the following steps:

The substrate 11 is cleaned in an ultrasonic cleaning device (not shown), filled with ethanol or acetone, to remove, e.g., grease, dirt, and/or impurities.

After the substrate 11 is cleaned, the substrate 11 is provided for surface roughening treatment. In this exemplary embodiment, the surface roughening treatment is sandblasting. A sandblasting apparatus is provided with sand having grains with a diameter in a range from about 0.05 μm to about 0.25 μm. The sandblasting process is performed under pressure in a range of about 0.1 MPa to about 0.15 MPa for about 5min to about 20 min. The angle for sandblasting is in a range from about 30 degrees to about 60 degrees. The distance between the sandblasting apparatus and the substrate 11 is in a range of from about 10 cm to about 20 cm. The material of the sand is chosen from one of oxide aluminum, oxide silicon, and carbide silicon. After the sandblasting process is completed, the surface of the substrate 11 has roughness in a range from about 0.05 μm to about 0.25 μm.

The substrate 11 may be positioned in a plating chamber of an ion plating machine (not shown). A target made of PTFE is fixed in the plating chamber. The plating chamber is evacuated to about 0.1×10⁻³ Pa. Argon (Ar, having a purity of about 99.999%) may be used as a working gas and injected into the chamber at a flow rate from about 30 standard cubic centimeter per minute (sccm) to about 60 sccm. Power is now applied to the ion plating machining and the target fixed in the plating chamber. The Ar is ionized to plasma. The plasma then strikes the surface of the target to ionize the PTFE. The ionized PTFE is deposited on the roughened surface of the substrate 11 to form the anti-finger film 13. The target is applied at a power of about 200 W-about 600 W. Depositing of the anti-fingerprint film 13 may take about 30 min to about 60 min. and the pressure is kept in a range from about 2 Pa to about 3 Pa during the depositing process.

From the above exemplary process, the PTFE forms a plurality of nano mastoid structures on the anti-fingerprint film 13. The coarse or rugged nature of the surface of the substrate 11 aids in the formation of the nano mastoid structures. A plurality of nano-sized pockets is defined between the nano mastoid structures. When water or oil contacts the surface of the anti-fingerprint film 13, the pockets are sealed by the water or oil trapping air which forms a protective layer to prevent the water or oil wetting the anti-fingerprint film 13 to achieve a good anti-fingerprint property. The anti-fingerprint film 13 has a wetting angle of over 92%. This evidences the exemplary anti-fingerprint film 13 has a good anti-fingerprint property.

The method uses an environmentally friendly vacuum sputtering process to get an anti-fingerprint property. In addition, the substrate adopts surface roughening treatment to allow the anti-fingerprint film to be firmly attached to the surface of the substrate, increasing mechanical stability of the anti-fingerprint film 13.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A device housing, comprising:
a substrate having roughness in a range from about 0.05 μm to about 0.25 μm; and
an anti-fingerprint film formed on the substrate, the anti-fingerprint film comprising a nano-composite coating consisting essentially of polytetrafluoroethylene.

2. The device housing as claimed in claim 1, wherein the anti-fingerprint film has a thickness under 2000 nm.

3. The device housing as claimed in claim 2, wherein the anti-fingerprint film has a thickness of about 100-500 nm.

4. The device housing as claimed in claim 1, wherein the substrate is made of metal or non-metal material.

5. The device housing as claimed in claim 1, wherein the anti-fingerprint film is formed on the substrate by ion plating.

6. A method for making a device housing, comprising:
providing a substrate;
roughening treatment the substrate to have roughness in a range from about 0.05 μm to about 0.25 μm; and
forming an anti-fingerprint film on the substrate by ion plating, the anti-fingerprint film comprising nano-composite coating consisting essentially of polytetrafluoroethylene.

7. The method as claimed in claim 6, wherein ion plating the anti-fingerprint film uses a target made of polytetrafluoroethylene; uses argon as a working gas, the argon has a flow rate of about 30-60 sccm, ion plating the anti-fingerprint film may take for about 30-60 minutes.

8. The method as claimed in claim 7, wherein the substrate is biased with a negative bias voltage of about −100V to about −300V during vacuum sputtering the anti-fingerprint film.

9. The method as claimed in claim 7, further comprising a step of pre-treating the substrate before forming the anti-fingerprint film.

10. The method as claimed in claim 9, wherein the pre-treating process comprising ultrasonic cleaning the substrate.

11. The method as claimed in claim 6, wherein the substrate is made of metal material or non-metal material.

12. The method as claimed in claim 11, wherein if the substrate is made of metal, the metal is selected from a group consisting of stainless steel, aluminum, aluminum alloy, copper, and copper alloy, and if the substrate is made on a non-metal material, the non-metal material is selected from the group consisting of plastic and ceramic.
